(19) United States
(12) Patent Application Publication
(10) Pub. No.: US 2026/0338858 A1
(43) Pub. Date: Oct. 29, 2026

(54) STRUCTURE AND METHOD FOR TESTING PERFORMANCE OF PACKAGED CHIP

(71) Applicant: MONTAGE TECHNOLOGY (KUNSHAN) CO., LTD., Suzhou, Jiangsu (CN)

(72) Inventors: Meng MEI, Suzhou (CN); Gang SHI, Suzhou (CN); Peichun WANG, Suzhou (CN); Guangfeng LI, Suzhou (CN)

(73) Assignee: MONTAGE TECHNOLOGY (KUNSHAN) CO., LTD., Suzhou, Jiangsu (CN)

(21) Appl. No.: 19/103,949

(22) PCT Filed: Feb. 22, 2023
(86) PCT No.: PCT/CN2023/077726

§ 371 Date: Feb. 14, 2025

(30) Foreign Application Priority Data
Aug. 16, 2022 (CN) 202210983387.1

(51) Int. Cl. G01R 31/28; G01R 31/71; H10W 72/20; H10W 90/00

(52) U.S. Cl. CPC G01R 31/2896; G01R 31/71; H10W 72/267; H10W 90/724

(57) ABSTRACT

Disclosed in the present application are a structure and method for testing the performance of a packaged chip. The structure may comprise a package substrate and a die, wherein the package substrate is provided with at least one unconnected solder ball; each corner area of the die is provided with at least one redundant bump; and the redundant bumps located in the corner areas are connected in series to the at least one unconnected solder ball to form a test loop. The present application can detect, by means of measuring the resistance value or capacitance value of the test loop, whether the package substrate and a package body of the die has the problem of non-wetting.

### TECHNICAL FIELD

The present application generally relates to the field of chip packaging technology, and particularly relates to a structure and method for testing performance of a packaged chip.

### BACKGROUND

According to IPC standards, non-wetting is defined as the inability of molten solder to form a metallic bond with substrate metal. This results in the inability of the solder to be captured on the solder points of the substrate, PCB pads, or components during the reflow process. As the sizes of the package substrate and the die increase, the thermal expansion coefficients (CTE) between the substrate and the die do not match, and the warpage increases, which will increase the non-wetting failure rate of the bumps on the die and the substrate. Moreover, as the package substrate becomes thinner and lighter, the warpage of the substrate will increase, which will increase the non-wetting failure rate of the bump and the substrate.

In addition, with the evolution of chip wafer node processes, in order to reduce the die size and make the traces on the package substrate more dense, embedded trace substrate (ETS) becomes a new option. Due to the fact that the pads (BOP) and traces (BOT) inside the ETS substrate are embedded into the package substrate, this will lead to a decrease in the contact area between the bumps and the pads or traces, increasing the non-wetting failure rate between the bumps and the substrate.

### SUMMARY OF THE INVENTION

An object of this application is to provide a structure and method for testing performance of a packaged chip, which can be used to detect whether there is non-wetting issue in a package body formed by the package substrate and the die. The structure is simple, the testing method is convenient, and the test can be conducted at any time, which helps to monitor the manufacturing process in real time.

This application discloses a structure for testing performance of a packaged chip, comprising: a package substrate, wherein the package substrate is provided with at least one unconnected solder ball;
a die, each corner area of the die is provided with at least one dummy bump, and the dummy bumps located in the corner areas and the at least one unconnected solder ball are connected in series to form a test loop.

In some embodiments, the dummy bumps located in different corner areas are electrically connected via substrate wiring, and the dummy bumps and the unconnected solder balls are electrically connected via substrate wiring.

In some embodiments, the dummy bumps located in the same corner area are electrically connected via a re-distributed layer inside the die, and a resistance value or a capacitance value of the test loop is tested though the at least one unconnected solder ball to determine whether there is a non-wetted dummy bump between the die and the package substrate.

In one embodiment, the package substrate is provided with one unconnected solder ball, and the capacitance value of the test loop is tested though the unconnected solder ball to determine whether there is a non-wetted dummy bump between the die and the package substrate.

In one embodiment, the package substrate is provided with two unconnected solder balls, and the resistance value of the test loop is tested though the two unconnected solder balls to determine whether there is a non-wetted dummy bump between the die and the package substrate.

In one embodiment, if the resistance value or the capacitance value indicates that the test loop is open, it is determined that there is a non-wetted dummy bump between the die and the package substrate.

In one embodiment, the re-distributed layer comprises aluminum, and a thickness of the re-distributed layer is 2 microns to 3 microns.

The present application also discloses a method for testing performance of a packaged chip. The method is applied to a structure for testing performance of the packaged chip, wherein the structure comprises: a package substrate, the package substrate being provided with at least one unconnected solder ball; and a die, each corner area of the die being provided with at least one dummy bump, and the dummy bumps located in the corner areas and the at least one unconnected solder ball being connected in series to form a test loop; the method comprises:
testing a resistance value or a capacitance value of the test loop by the at least one unconnected solder ball to determine whether there is a non-wetted dummy bump between the die and the package substrate.

In one embodiment, after determining that there is no non-wetted dummy bump between the die and the package substrate, the method further comprises:
disconnecting the re-distributed layer between the dummy bumps located in the same corner area, and connecting the dummy bumps located in the same corner area via a bottom metal layer of a metal interconnect layer inside the die, and selectively testing a resistance value or a capacitance value of the test loop by at least one unconnected solder ball to determine whether there is a crack in the bottom metal layer of the metal interconnect layer.

In one embodiment, the bottom metal layer is an ultra-low dielectric layer, and a thickness of the ultra-low dielectric layer is 0.2 microns to 0.5 microns.

An implementation of the present application connects the unconnected solder ball on the package substrate to the dummy bumps at the corner areas of the die to form a test structure. It is only necessary to test the resistance value or capacitance value of the structure through the unconnected solder ball to determine whether the packaging body of the package substrate and the die has the problem of non-wetting. Therefore, this test structure is simple and easy to build, and the test method is convenient, which is conducive to monitor the manufacturing process in real-time.

Furthermore, after determining that the package does not have the problem of non-wetting, the present application simply adjusts the connection lines between the dummy bumps in the same corner area, that is, the dummy bumps located in the same corner area are connected via the bottom metal layer of the metal interconnect layer inside the die, and then the resistance value or capacitance value of the structure is tested though the unconnected solder ball to determine whether there is a crack in the bottom metal layer of the metal interconnect layer.

### BRIEF DESCRIPTION OF THE FIGURES

FIG. 1 illustrates a schematic diagram of a structure for testing performance of a packaged chip according to one embodiment of the present application.

FIG. 2 shows a schematic cross-sectional view of a metal interconnect layer in a die according to one embodiment of the present application.

### DETAILED DESCRIPTION

In the following description, numerous technical details are set forth in order to provide the readers with a better understanding of the present application. However, those skilled in the art can understand that the technical solutions claimed in the present application can be implemented without these technical details and various changes and modifications based on the following embodiments.

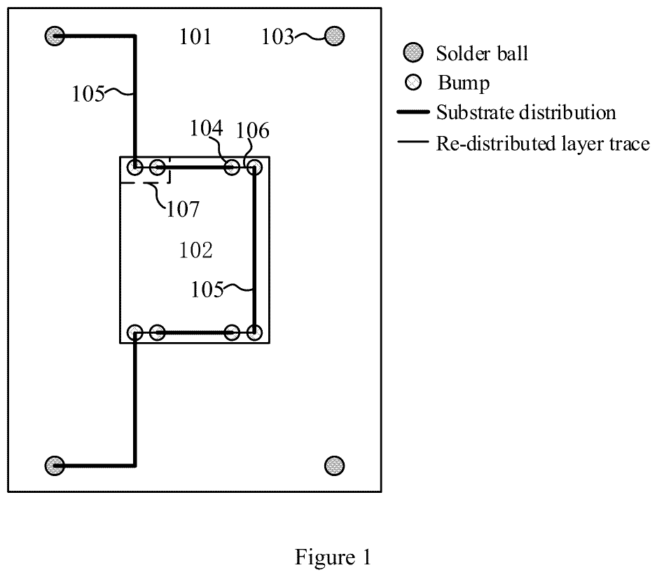

The application discloses a structure for testing performance of a packaged chip, and FIG. 1 shows a schematic diagram of the structure for testing performance of the packaged chip according to one embodiment. The structure comprises a package substrate (such as a printed circuit board, PCB) 101 and a die 102. At least one unconnected solder ball 103 is provided on the package substrate 101. For example, in the example of FIG. 1, the package substrate 101 is provided with four unconnected solder balls 103. It should be understood that the number of unconnected solder balls 103 disposed on the package substrate 101 in the present embodiment is not limited to this. At least one dummy bump 104 is provided in each corner area 107 of the die 102. In the example of FIG. 1, each corner area 107 is provided with two dummy bumps 104. It should be understood that the number of dummy bumps 104 disposed in each corner area 107 is not limited to this. In addition, it should be noted that in addition to the corner area 107, an embodiment of the present application can also dispose dummy bumps 104 in other edge areas of the die or other areas where the non-wetting is prone to occur, so as to increase a detection probability. It should be understood that in addition to the dummy bumps 104 disposed in the corner area 107 of the die 102, a central area of the die 102 is also provided with bumps that electrically connect the internal structure of the die. The dummy bumps 104 located in each corner area 107 and the at least one unconnected solder ball 103 are connected in series to form a test loop.

In one embodiment, the dummy bumps 104 located in different corner areas 107 are electrically connected via substrate wiring 105, and the dummy bumps 104 and the unconnected solder balls 103 are electrically connected via substrate wiring 105.

In one embodiment, the dummy bumps 104 located in the same corner area 107 are electrically connected via the Re-distributed layer (RDL) 106 inside the die 102. In one embodiment, the RDL 106 comprises aluminum, and the thickness of the RDL 106 is 2-3 microns, for example, the thickness of the RDL 106 may be 2.3 microns, 2.5 microns, 2.8 microns, etc.

After the test loop is formed as described above, a resistance value or a capacitance value of the test loop is tested through the at least one unconnected solder ball 103 to determine whether there is a non-wetted dummy bump 104 between the die 102 and the package substrate 101.

In one embodiment, the package substrate 101 is provided with one unconnected solder ball 103, and the capacitance value of the test loop is tested through the unconnected solder ball 103 to determine whether there is a non-wetted dummy bump 104 between the die 102 and the package substrate 101. For example, a multimeter can be used to measure the capacitance value between the unconnected solder ball 103 and a power supply or ground. If the capacitance value indicates that the test loop is open, it is determined that there is a non-wetted dummy bump 104 between the die 102 and the package substrate 101.

In another embodiment, the package substrate 101 is provided with two or more unconnected solder balls 103, and the test loop only needs to include two of the unconnected solder balls 103. A resistance value of the test loop is tested though the two unconnected solder balls 103 to determine whether there is a non-wetted dummy bump 104 between the die 102 and the package substrate 101. For example, the resistance value between the two unconnected solder balls 103 can be tested, and if the resistance value indicates that the test loop is open, it can be determined that there is a non-wetted dummy bump 104 between the die 102 and the package substrate 101.

It should be understood that before packaging the package substrate 101 and the die 102, the package substrate 101 and the die 102 have each been subjected to corresponding tests, that is, the electrical tests for the package substrate 101, for the die 102 and between the package substrate 101 and the die 102 are all passed. The application can further test to determine whether there is a non-wetted dummy bump 104 between the die 102 and the package substrate 101.

In another embodiment of the present application, a method for testing performance of the packaged chip is also disclosed, wherein the method is applied to a structure for testing the performance of the packaged chip, such as the structure shown in FIG. 1. The structure comprises a package substrate 101 and a die 102. The package substrate 101 is provided with at least one unconnected solder ball 103. Each corner area 107 of the die 102 is provided with at least one dummy bump 104. The dummy bumps 104 located in each corner area 107 and the at least one unconnected solder ball 103 are connected in series to form a test loop. The dummy bumps 104 located in different corner areas are electrically connected via the RDL 106 inside the die 102, and the dummy bumps 104 and the unconnected solder ball 103 are electrically connected via the RDL 106 inside the die 102. In one embodiment, the RDL 106 comprises aluminum, and the thickness of the RDL 106 may be 2 microns to 3 microns. The method comprises:
selectively testing a resistance value or a capacitance value of the test loop though the at least one unconnected solder ball 103 to determine whether there is a non-wetted dummy bump between the die and the package substrate.

In one embodiment, selectively testing a resistance value or a capacitance value of the test loop though the at least one unconnected solder ball 103 may comprise the following situations:
(i) If there is one unconnected solder ball 103 disposed on the package substrate 101, the capacitance value of the test loop is tested though the unconnected solder ball 103. When the capacitance value indicates that the test loop is open, it is determined that there is a non-wetted dummy bump 104 between the die 102 and the package substrate 101.
(ii) If there are two or more unconnected solder balls 103 disposed on the package substrate 102, only two of the unconnected solder balls 103 need to be included in the test loop, and the resistance value of the test loop is tested though the two unconnected solder balls 103. When the resistance value indicates that the test loop is open, it is determined that there is a non-wetted dummy bump 104 between the die 102 and the package substrate 101.

In one embodiment, after determining that there is no non-wetted dummy bump between the die 102 and the package substrate 101, the method may further comprise: disconnecting the RDL 106 between the dummy bumps 104 located in the same corner area, and connecting the dummy bumps 104 located in the same corner area via a bottom metal layer of a metal interconnect layer inside the die 101, and selectively testing a resistance value or a capacitance value of the test loop though at least one unconnected solder ball 103 to determine whether there is a crack in the bottom metal layer of the metal interconnect layer. The bottom metal layer is an ultra-low dielectric layer, with a thickness ranging from 0.2 microns to 0.5 microns. For example, the thickness of the ultra-low dielectric layer may be 0.21 microns, 0.3 microns, 0.4 microns, 0.46 microns, etc.

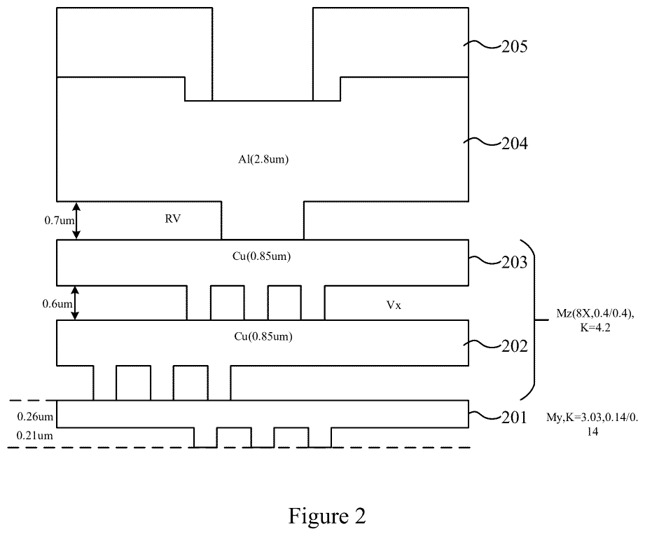

FIG. 2 shows a schematic cross-sectional view of a metal interconnect layer in a die according to one embodiment of the present application. In this embodiment, the metal interconnect layer comprises a plurality of metal layers, and a dielectric layer is formed between adjacent metal layers (not shown in the figure). Wherein, the bottom metal layer 201 adopts an ultra-low dielectric layer (ELK), for example, the dielectric constant K is 3.03, and the dielectric constants of the metal layers 202 and 203 above the bottom metal layer 201 are greater than those of the bottom metal layer 201. For example, the dielectric constant K of the metal layers 202 and 203 is 4.2. A RDL 204 and a passivation layer 205 are formed on the metal layer 203. After determining that there is no non-wetted dummy bump between the die and the package substrate, the RDL 204 between the dummy bumps located in the same corner area is disconnected, and the dummy bumps located in the same corner area are connected via the bottom metal layer 201 of the metal interconnect layer inside the die, and the resistance value or the capacitance value of the test loop is selectively tested by the at least one unconnected solder ball to determine whether there is a crack in the bottom metal layer of the metal interconnect layer. When the resistance value or the capacitance value indicates that the test loop is open, it is determined that there is a crack in the bottom metal layer of the metal interconnect layer.

Since the connection between the die and the package substrate experiences the highest stress in the corner areas, the corner areas are most likely to have the problem of non-wetting. Therefore, if the unconnected solder ball(s) on the package substrate is connected to the dummy bumps on each corner area of the die, with the adjacent dummy bumps in the same corner area being connected via the RDL on the package substrate, the dummy bumps in different corner areas being electrically connected via substrate wiring, and the dummy bumps and the unconnected solder balls being electrically connected via substrate wiring, a test loop can be formed to detect whether there is a non-wetted dummy bump.

Since the package substrate has passed the O/S (Open/Short) test, the die has also passed the probe O/S test. In the test loop, the connection point between the package substrate and the die is the dummy bumps. If any of the dummy bumps are non-wetted, an open circuit will occur between the two unconnected solder balls, which can be detected by measuring the DC resistance value of the test loop. If there is only one unconnected solder ball, it can be detected by measuring the capacitance value between the unconnected solder ball and a reference solder ball, for example, the reference solder ball can be a ground voltage or a power supply voltage. Of course, in other embodiments of this application, more dummy bumps can be added to increase the detection probability of non-wetting bumps.

The test structure takes into account that the connection between the die and the package substrate experiences the highest stress in the corner area. At the same time, for large-sized dies, dummy bumps are required. Considering that the mechanical support of the corner area of the die and the PCB will also require the presence of unconnected solder balls, the present application will not increase the area of the die and the package area.

The test structure only needs to add a transmission line to the packaged structure. Since it mainly tests DC resistance or capacitance, there is no requirement for signal integrity. The added transmission line can be segmented and routed in the plurality of layers, which basically does not change the existing package design. This test structure only requires adding one segment of RDL routing to the die, which will have little impact on the design of the die. At the same time, some structures can be added below the dummy bumps of the die, such as using ELK layer wire interconnection instead of RDL connection, to detect whether cracks occur in the ELK layer.

The testing process only requires a multimeter for detection. Real-time monitoring can be achieved in the manufacture of surface mount technology (SMT) between the die and the PCB, and real-time establishment can also be achieved during reliability testing of the die, making it convenient to monitor the manufacturing process.

It should be noted that in this specification of the application, relational terms such as the first and second, and so on are only configured to distinguish one entity or operation from another entity or operation, and do not necessarily require or imply any such actual relationship or order between these entities or operations. Furthermore, the term “comprises” or “comprising” or “includes” or any other variations thereof is intended to encompass a non-exclusive inclusion, such that a process, method, article, or device that comprises a multiple elements includes not only those elements but also other elements, or elements that are inherent to such a process, method, item, or device. Without more restrictions, the element defined by the phrase “comprise(s) a/an” does not exclude that there are other identical elements in the process, method, item or device that includes the element. In this specification of the application, if it is mentioned that an action is performed according to an element, it means the meaning of performing the action at least according to the element, and includes two cases: the action is performed only on the basis of the element, and the action is performed based on the element and other elements. Multiple, repeatedly, various, etc., expressions include 2, twice, 2 types, and 2 or more, twice or more, and 2 types or more types.

The specification includes combinations of the various embodiments described herein. Separate references to embodiments (such as “an embodiment” or “some embodiments” or “preferred embodiments”) do not necessarily refer to the same embodiment; however, these embodiments are not mutually exclusive unless indicated as mutually exclusive or clearly mutually exclusive by those skilled in the art. It should be noted that unless the context clearly indicates or requires otherwise, the word “or” is used in this specification in a non-exclusive sense.

All documents mentioned in this specification are considered to be included in the disclosure of this application as a whole, so that they can be used as a basis for modification when necessary. In addition, it should be understood that the above descriptions are only preferred embodiments of this specification, and are not intended to limit the protection scope of this specification. Any modification, equivalent replacement, improvement, etc. made within the spirit and principle of one or more embodiments of this specification should be included in the protection scope of one or more embodiments of this specification.

1. A structure for testing performance of a packaged chip, comprising:
a package substrate, wherein the package substrate is provided with at least one unconnected solder ball;
a die, each corner area of the die is provided with at least one dummy bump, and the dummy bumps located in the corner areas and the at least one unconnected solder ball are connected in series to form a test loop.

2. The structure for testing performance of the packaged chip according to claim 1, wherein the dummy bumps located in different corner areas are electrically connected via substrate wiring, and the dummy bumps and the unconnected solder balls are electrically connected via substrate wiring.

3. The structure for testing performance of the packaged chip according to claim 1, wherein the dummy bumps located in the same corner area are electrically connected via a re-distributed layer inside the die, and a resistance value or a capacitance value of the test loop is tested though the at least one unconnected solder ball to determine whether there is a non-wetted dummy bump between the die and the package substrate.

4. The structure for testing performance of the packaged chip according to claim 3, wherein the package substrate is provided with one unconnected solder ball, and the capacitance value of the test loop is tested though the unconnected solder ball to determine whether there is a non-wetted dummy bump between the die and the package substrate.

5. The structure for testing performance of the packaged chip according to claim 3, wherein the package substrate is provided with two unconnected solder balls, and the resistance value of the test loop is tested though the two unconnected solder balls to determine whether there is a non-wetted dummy bump between the die and the package substrate.

6. The structure for testing performance of the packaged chip according to claim 3, wherein if the resistance value or the capacitance value indicates that the test loop is open, it is determined that there is a non-wetted dummy bump between the die and the package substrate.

7. The structure for testing performance of the packaged chip according to claim 3, wherein the re-distributed layer comprises aluminum, and a thickness of the re-distributed layer is 2 microns to 3 microns.

8. A method for testing performance of a packaged chip, wherein the method is applied to a structure for testing performance of the packaged chip, the structure comprises: a package substrate, the package substrate being provided with at least one unconnected solder ball; and a die, each corner area of the die being provided with at least one dummy bump, and the dummy bumps located in the corner areas and the at least one unconnected solder ball being connected in series to form a test loop; the method comprises:
testing a resistance value or a capacitance value of the test loop by the at least one unconnected solder ball to determine whether there is a non-wetted dummy bump between the die and the package substrate.

9. The method for testing performance of the packaged chip according to claim 8, wherein selectively testing a resistance value or a capacitance value of the test loop by the at least one unconnected solder ball, comprising:
if the package substrate is provided with one unconnected solder ball, testing the capacitance value of the test loop though the unconnected solder ball; and
if the package substrate is provided with two unconnected solder balls, testing the resistance value of the test loop though the two unconnected solder balls.

10. The method for testing performance of the packaged chip according to claim 8, wherein the method comprises determining there is a non-wetted dummy bump between the die and the package substrate if the resistance value or the capacitance value indicates that the test loop is open.

11. The method for testing performance of the packaged chip according to claim 8, wherein the dummy bumps located in different corner areas are electrically connected via substrate wiring, and the dummy bumps and the unconnected solder balls are electrically connected via substrate wiring.

12. The method for testing performance of the packaged chip according to claim 8, wherein the dummy bumps located in the same corner area are electrically connected via a re-distributed layer inside the die.

13. The method for testing performance of the packaged chip according to claim 12, wherein after determining that there is no non-wetted dummy bump between the die and the package substrate, the method further comprises:
disconnecting the re-distributed layer between the dummy bumps located in the same corner area, and connecting the dummy bumps located in the same corner area via a bottom metal layer of a metal interconnect layer inside the die, and selectively testing a resistance value or a capacitance value of the test loop by at least one unconnected solder ball to determine whether there is a crack in the bottom metal layer of the metal interconnect layer.

14. The method for testing performance of the packaged chip according to claim 12, wherein the re-distributed layer comprises aluminum, and a thickness of the re-distributed layer is 2 microns to 3 microns.

15. The method for testing performance of the packaged chip according to claim 13, wherein the bottom metal layer is an ultra-low dielectric layer, and a thickness of the ultra-low dielectric layer is 0.2 microns to 0.5 microns.
